(19) United States
(12) Patent Application Publication
(10) Pub. No.: US 2008/0176351 A1
(43) Pub. Date: Jul. 24, 2008

(54) MANUFACTURING METHOD OF DISPLAY DEVICE

(76) Inventors: Hideaki Shimmoto, Toyokawa (JP); Takahiro Kamo, Shibuya (JP); Takeshi Noda, Mobara (JP); Takuo Kaitoh, Mobara (JP); Eiji Oue, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/843,693

(22) Filed: Aug. 23, 2007

(30) Foreign Application Priority Data
Aug. 24, 2006 (JP) 2006-227283

(51) Int. Cl. H01L 21/00

(52) U.S. Cl. 438/36; 257/E21.412

(57) ABSTRACT

The present invention provides a manufacturing method of a display device which can prevent the reduction of a size of a pseudo single-crystalline region having strip-like crystals in forming such a pseudo single-crystalline silicon region on a substrate. A step for forming pseudo single crystals having strip-like crystals on a preset region of a semiconductor film formed on a substrate includes a step for forming the pseudo single crystal by radiating an energy beam to a first region of the semiconductor film while moving a radiation position of the energy beam in a first direction, and a step for forming the pseudo single crystal by radiating the energy beam to a second region of the semiconductor film while moving a radiation position of the energy beam in a second direction opposite to the first direction. The first region and the second region set sizes thereof at a position where the radiation of the energy beam is finished smaller than sizes thereof at a position where the radiation of the energy beam is started. The second region includes a portion where the second region overlaps the first region and a portion where the second region does not overlap the first region.

The present application claims priority from Japanese application JP2006-227283 filed on Aug. 24, 2006, the content of which is hereby incorporated by reference into this application.

### BACKGROUND OF THE INVENTION

The present invention relates to a manufacturing method of a display device, and more particularly to a technique which is effectively applicable to a manufacturing method of a substrate (a TFT substrate) which is used in a liquid crystal display panel.

Conventionally, with respect to liquid crystal display devices, there has been known a liquid crystal display device which uses an active-matrix-type liquid crystal display panel. In the active-matrix-type liquid crystal display panel, in a display region of one of a pair of substrates which sandwiches a liquid crystal material therebetween, active elements (switching elements) such as TFT elements are arranged in a matrix array.

In the active-matrix-type liquid crystal display panel, a semiconductor layer (channel layer) of the TFT element is, in general, made of amorphous silicon (a-Si) or poly-crystalline silicon (poly-Si). When the semiconductor layer of the TFT element is made of poly-crystalline silicon, for example, an amorphous silicon film is formed on a substrate and, thereafter, amorphous silicon is melted and crystallized by radiating an energy beam such as a laser beam to form a poly-crystalline silicon film. Further, to enhance the mobility of carriers in the TFT element, there may be a case that an energy beam such as a laser beam is again radiated to the poly-crystalline silicon films to melt and recrystalize silicon into a granular crystalline state thus forming a poly-crystalline silicon film which is constituted of a mass of strip-like crystals which extends in an elongated manner in a specific direction. Here, the strip-like crystals grow in an elongated manner in the direction along the moving direction of a radiation position of the energy beam on the substrate. Hereinafter, the poly-crystalline silicon which is formed of a mass of strip-like crystals is referred to as pseudo single-crystalline silicon.

Here, in the active-matrix-type liquid crystal display panel, on the substrate on which the TFT elements are formed (hereinafter, referred to as the TFT substrate), a plurality of scanning signal lines and a plurality of video signal lines are formed. A scanning signal is inputted to the respective scanning signal lines from a drive circuit referred to as a scanning driver or the like. On the other hand, a video signal (gray-scale data) is inputted to the respective video signal lines from a drive circuit referred to as a data driver or the like.

Further, in the conventional liquid crystal display device, the drive circuit which inputs the scanning signal to the respective scanning signal lines and the drive circuit which inputs the video signal to the respective video signal lines are formed on an IC chip referred to as a driver IC and, for example, a TCP or a COF which mounts the driver IC on a flexible printed circuit board is connected to the TFT substrate. Further, besides such a connection, for example, the driver IC may be directly mounted on the TFT substrate.

Further, in recent years, there has been also proposed a method which, in a manufacturing step of the TFT substrate, integrally forms a drive circuit (an integrated circuit) having a function equivalent to a function of the driver IC outside a display region of the TFT substrate with the TFT substrate.

Here, the drive circuit which is formed outside the display region of the TFT substrate includes a large number of semiconductor elements such as MOS transistors. Further, a semiconductor layer of the semiconductor element may preferably be made of pseudo single-crystalline silicon which exhibits the higher carrier mobility than amorphous silicon and poly-crystalline silicon.

In the manufacturing step of the TFT substrate, in generating an energy beam which is radiated for reforming or modifying the amorphous silicon or the poly-crystalline silicon formed on an insulating substrate such as a glass substrate into the pseudo single-crystalline silicon, for example, a continuous oscillation laser is used in general.

### SUMMARY OF THE INVENTION

In the conventional manufacturing step of the TFT substrate, in forming the pseudo single-crystalline silicon by radiating continuous oscillation laser beam to predetermined regions such as regions for forming TFT elements on the display region or drive circuits outside the display region out of the amorphous silicon or the poly-crystalline silicon formed on the insulation substrate, for example, the radiation of the continuous oscillation laser beam is performed while moving the radiation position of the continuous oscillation laser beam on the insulation substrate in a specific direction.

However, inventors of the present invention have made the following finding. That is, for example, when the laser beam is radiated to one region out of the plurality of regions on the insulation substrate where the pseudo single-crystalline silicon is formed while moving the radiation position of the laser beam in the first direction, a size of the region in the direction orthogonal to the first direction at a position where the radiation of the laser beam is finished becomes smaller than the size of the region orthogonal to the first direction at a position where the radiation of the laser beam is started.

That is, the inventors of the present invention have found that particularly when the laser to be radiated is the continuous oscillation laser which radiates a single beam having laser power of 30 W or more or a synthesized beam having laser power of 30 W or more in total at an oscillation source, for example, in radiating the beam by condensing using an object lens, the above-mentioned phenomenon which reduces the size of the region is liable to easily occur.

Here, although an accurate reason which explains the cause of such a phenomenon has still not yet been found, for example, it is estimated that a focal point is deviated in the course of radiation of laser beam due to the deformation of the object lens attributed to temperature elevation. As reference data, the condensed laser power at a point of time that the laser beam is radiated to the amorphous silicon film or the poly-crystalline silicon film is 20 W.

In this manner, when the size of the region in the direction orthogonal to the first direction at the position where the radiation of the laser beam is finished becomes smaller than the size of the region in the direction orthogonal to the first direction at the position where the radiation of the laser beam is started, for example, a region which is still made of the poly-crystalline silicon remains in the region where the drive circuit is formed thus giving rise to a drawback that an operational characteristic of a MOS transistor formed in the region is lowered.

It is an advantage of the present invention to provide a technique which can prevent, when a region which is made of poly-crystalline silicon (pseudo single-crystalline silicon) formed of a mass of strip-like crystals which is elongated in a specific direction is formed on a substrate, a size of the region in the region from becoming smaller in the specific direction.

The above-mentioned and other objects and novel features of the present invention will become apparent from the description of this specification and attached drawings.

The following is an explanation of the summary of typical inventions among the inventions disclosed in this specification.

(1) The present invention provides a manufacturing method of a display device having a step for forming pseudo single crystal which has strip-like crystals in preset regions of a semiconductor film formed on a substrate by radiating an energy beam to the semiconductor film, wherein the step for forming the pseudo single crystal includes a first step for forming the pseudo single crystal by radiating the energy beam to a first region of the semiconductor film while moving a radiation position of the energy beam on the substrate in a first direction, and a second step for forming the pseudo single crystal by radiating the energy beam to a second region of the semiconductor film while moving a radiation position of the energy beam on the substrate in a second direction opposite to the first direction, and the first region and the second region in which the pseudo single crystal is formed by the respective steps consisting of the first step and the second step respectively set sizes thereof in a direction orthogonal to the moving direction of the radiation position at a position where the radiation of the energy beam is finished smaller than sizes thereof in the direction orthogonal to the moving direction of the radiation position at a position where the radiation of the energy beam is started, and the second region includes a portion where the second region overlaps the first region and a portion where the second region does not overlap the first region.

(2) In the manufacturing method of a display device having the above-mentioned constitution (1), in overlapping the first region and the second region, the position where the radiation of energy beam is finished in the first step is arranged between the position where the radiation of energy beam is started in the first step and the position where the radiation of energy beam is started in the second step, and is arranged on a side closer to the position where the radiation of energy beam is started in the second step than a center position between the position where the radiation of the energy beam is started in the first step and the position where the radiation of the energy beam is started in the second step.

(3) In the manufacturing method of a display device having the above-mentioned constitution (1) or (2), the energy beam is a continuous oscillation laser beam.

(4) In the manufacturing method of a display device having any one of the above-mentioned constitutions (1) to (3), the semiconductor film before forming the pseudo single crystal is an amorphous silicon film.

(5) In the manufacturing method of a display device having any one of the above-mentioned constitutions (1) to (3), the semiconductor film before forming the pseudo single crystal is a poly-crystalline silicon film.

(6) In the manufacturing method of a display device having any one of the above-mentioned constitutions (1) to (5), a position of a center axis along the extending direction of the first region is substantially equal to a center axis along the extending direction of the second region.

According to the manufacturing method of a display device of the present invention, for example, in the region where the pseudo single crystal is formed in the first step, even when the size of the region in the direction orthogonal to the moving direction of the radiation position at the position where the radiation of the energy beam is finished becomes smaller than the size of the region in the direction orthogonal to the moving direction of the radiation position at the position where the radiation of the energy beam is started, in the second step, by moving the radiation position of the energy beam in the second direction from the vicinity of the position where the radiation of the energy beam is finished in the first step, the energy beam is radiated to the region where a width of the energy beam is narrowed and the pseudo single crystal is not formed in the first step thus forming the region into the pseudo single crystal.

Accordingly, in forming the pseudo single-crystal region having the strip-like crystals on the substrate, it is possible to prevent the size of the region from becoming smaller along the specific region.

### BRIEF DESCRIPTION OF THE DRAWINGS

FIG. 1A is a schematic plan view showing the schematic constitution of a liquid crystal display panel;

FIG. 1B is a schematic cross-sectional view showing the cross-sectional constitution taken along a line A-A′ in FIG. 1A;

FIG. 2 is a schematic plan view showing one example of the constitution of a TFT substrate of the liquid crystal display panel;

FIG. 3 is a schematic circuit diagram showing one example of the circuit constitution of one pixel in a display region of the TFT substrate;

FIG. 4A is a schematic plan view of a mother glass immediately after forming an amorphous silicon film;

FIG. 4B is a schematic cross-sectional view showing the cross-sectional constitution taken along a line B-B′ in FIG. 4A;

FIG. 5A is a schematic plan view of the mother glass immediately after forming a portion of the amorphous silicon film into poly-crystalline silicon;

FIG. 5B is a schematic cross-sectional view showing the cross-sectional constitution taken along a line C-C′ in FIG. 5A;

FIG. 6A is a schematic plan view of the mother glass immediately after forming the poly-crystalline silicon region into pseudo single crystal;

FIG. 6B is a schematic cross-sectional view showing the cross-sectional constitution taken along a line D-D′ in FIG. 6A;

FIG. 7 is a schematic perspective view for explaining methods for forming poly-crystalline silicon and pseudo single crystals;

FIG. 8 is a schematic plan view showing a mode in which the poly-crystalline silicon is formed into pseudo single crystal;

FIG. 9 is a schematic plan view for explaining steps for forming the pseudo single crystal to which the present invention is applied;

FIG. 10A is a schematic plan view for explaining drawbacks when the pseudo single-crystalline silicon is formed by radiating a continuous oscillation laser beam in one direction;

FIG. 10B is a schematic view for explaining the manner of operation and advantageous effects when the laser beam is radiated by a method adopted by the embodiment 1;

FIG. 11 is a schematic view for explaining a first modification of the manufacturing method of the TFT substrate in the embodiment 1;

FIG. 12 is a schematic plan view for explaining a second modification for forming the pseudo single crystals;

FIG. 13 is a schematic plan view showing an effective region when the pseudo single crystals are formed using a method shown in FIG. 12;

FIG. 14 is a schematic plan view for explaining one example of a radiation method of the continuous oscillation laser beam in forming a plurality of regions arranged in parallel in the x direction into pseudo single crystals;

FIG. 15 is a schematic plan view showing drawbacks which may arise when a continuous oscillation laser beam is radiated by the method shown in FIG. 14;

FIG. 16 is a schematic view for explaining one example of the radiation method of the continuous oscillation laser beam for overcoming the drawback shown in FIG. 15; and

FIG. 17 is a schematic view for explaining a variation of a manufacturing method of a TFT substrate in the embodiment 1.

### DESCRIPTION OF THE PREFERRED EMBODIMENTS

Hereinafter, the present invention is explained in detail in conjunction with an embodiment by reference to drawings.

Here, in all drawings for explaining the embodiment, parts having identical functions are given same symbols and their repeated explanation is omitted.

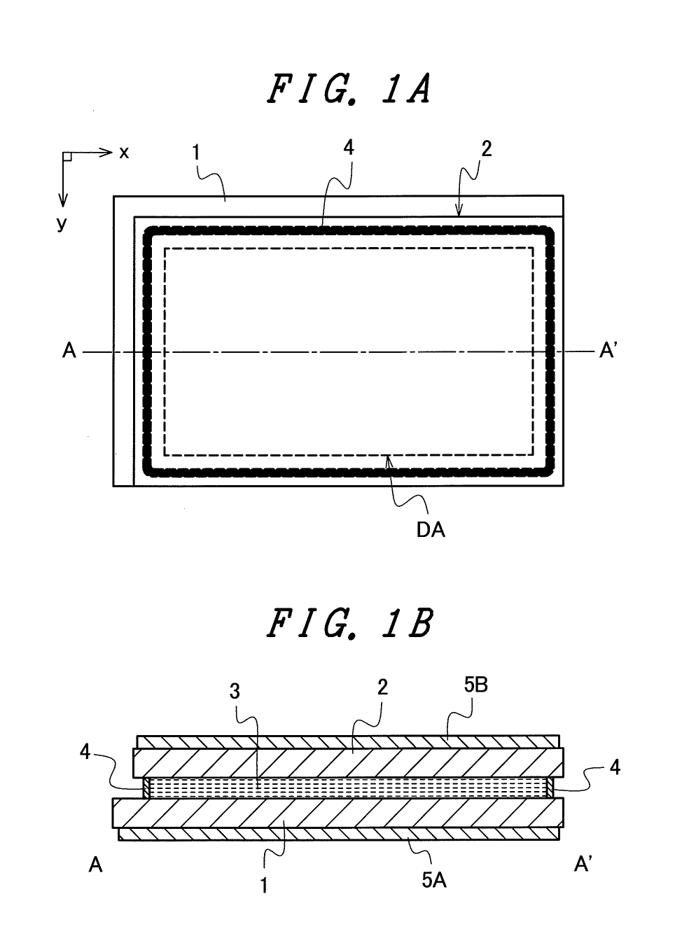

FIG. 1A to FIG. 3 are schematic views showing one constitutional example of a display device manufactured by applying the present invention.

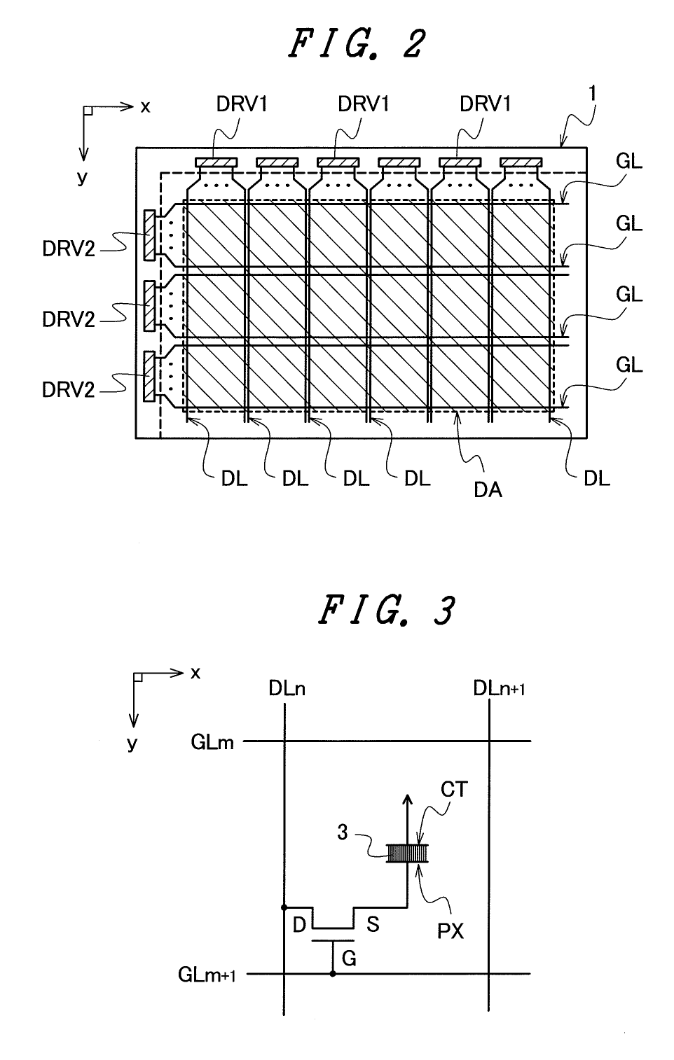

FIG. 1A is a schematic plan view showing the schematic constitution of a liquid crystal display panel. FIG. 1B is a schematic cross-sectional view showing the cross-sectional constitution taken along a line A-A′ in FIG. 1A. FIG. 2 is a schematic plan view showing one example of the constitution of a TFT substrate of the liquid crystal display panel. FIG. 3 is a schematic circuit diagram showing one example of the circuit constitution of one pixel in a display region of the TFT substrate.

A manufacturing method of the display device according to the present invention is applicable to the manufacture of a substrate of a liquid crystal display panel which is referred to as a TFT substrate. The liquid crystal display panel is, for example, as shown in FIG. 1A and FIG. 1B, a display panel which seals a liquid crystal material 3 between a pair of substrates consisting of a TFT substrate 1 and a counter substrate 2. Here, the TFT substrate 1 and the counter substrate 2 are adhered to each other using a sealing material 4 which is formed to surround a display region DA, and the liquid crystal material 3 is hermetically sealed in the space surrounded by the TFT substrate 1, the counter substrate 2 and the sealing material 4. Further, to surfaces of the TFT substrate 1 and the counter substrate 2 which face the outside, for example, polarizers 5A, 5B are adhered. Here, a phase difference plate having one to several layers may be arranged between the TFT substrate 1 and the polarizer 5A and between the counter substrate 2 and the polarizer 5B.

Further, on the TFT substrate 1, for example, as shown in FIG. 2, a plurality of scanning signal lines GL which extends in the x direction and laterally traverses the display region DA and a plurality of video signal lines DL which extends in the y direction and longitudinally traverses the display region DA are formed. Further, in the display region DA, a plurality of pixels which constitutes a mass is arranged two dimensionally in the x direction as well as in the y direction. Here, as shown in FIG. 3, one pixel region of the display region DA corresponds to a region which is surrounded by two neighboring scanning signal lines GLₘ, GLₘ₊₁ and two neighboring video signal lines GLₙ, GLₙ₊₁. In each pixel, a TFT element which constitutes a switching element and a pixel electrode PX are arranged. Here, the TFT element which is arranged for each pixel has, for example, a gate (G) thereof connected to one scanning signal line GLₘ₊₁ out of two neighboring scanning signal lines and a drain (D) thereof connected to one video signal line GLₙ out of two neighboring video signal lines. Further, the TFT element arranged for each pixel has a source (S) thereof connected to the pixel electrode PX. Still further, the pixel electrode PX forms a pixel capacitance together with a common electrode CT (also referred to as a counter electrode) and the liquid crystal material 3. Here, the common electrode CT may be formed on the counter substrate 2 or may be formed on the TFT substrate 1.

Further, on the TFT substrate 1 to which the present invention is applied, for example, as shown in FIG. 2, outside the display region DA, a first drive circuit DRV1 for inputting a video signal to the respective video signal lines DL and a second drive circuit DRV2 for inputting a scanning signal to the respective scanning signal line GL are formed. The first drive circuit DRV1 is a circuit having a function equivalent to a function of a conventional data driver IC, and includes a circuit for generating the video signal (gray scale data) inputted to the respective video signal lines DL, a circuit which controls inputting timing and the like, for example. Further, the second drive circuit DRV2 is a circuit having a function equivalent to a function of a conventional scanning driver IC, and includes a circuit for controlling timing at which the scanning signal is inputted to the respective scanning signal lines GL and the like, for example. Here, the first drive circuit DRV1 and the second drive circuit DRV2 are respectively formed of an integrated circuit which is constituted by combining a plurality of semiconductor elements such as MOS transistors or diodes.

Further, in the TFT substrate 1 to which the present invention is applied, the first drive circuit DRV1 and the second drive circuit DRV2 are not formed of an IC chip and constitute built-in circuits which are formed together with the scanning signal lines GL, the video signal lines DL, the TFT elements of the display region DA and the like on the TFT substrate 1. Here, although it is desirable to form the first drive circuit DRV1 and the second drive circuit DRV2 inside the sealing material 4, that is, between the sealing material 4 and the display region DA, the first drive circuit DRV1 and the second drive circuit DRV2 may be formed in a region which overlaps the sealing material 4 in a plan view or outside the sealing material 4.

Hereinafter, an embodiment of a case in which the present invention is applied to the manufacturing method of the TFT substrate 1 having the constitution shown in FIG. 2 and FIG. 3 is explained.

### EMBODIMENT 1

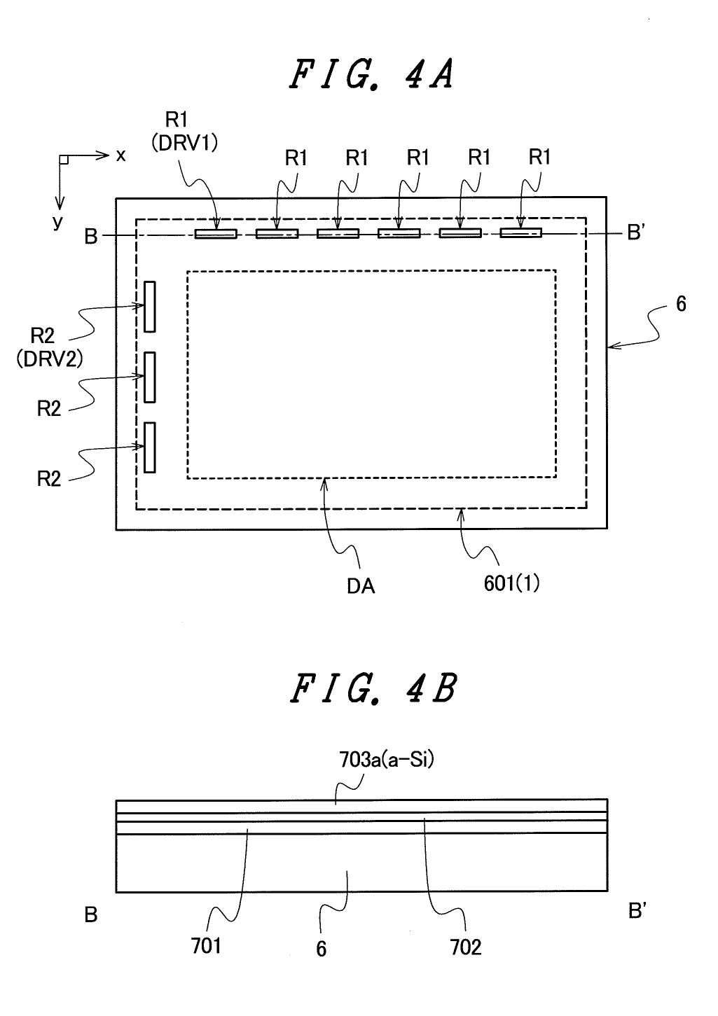

FIG. 4A to FIG. 9 are schematic views for explaining the manufacturing method of a TFT substrate of an embodiment 1 according to the present invention.

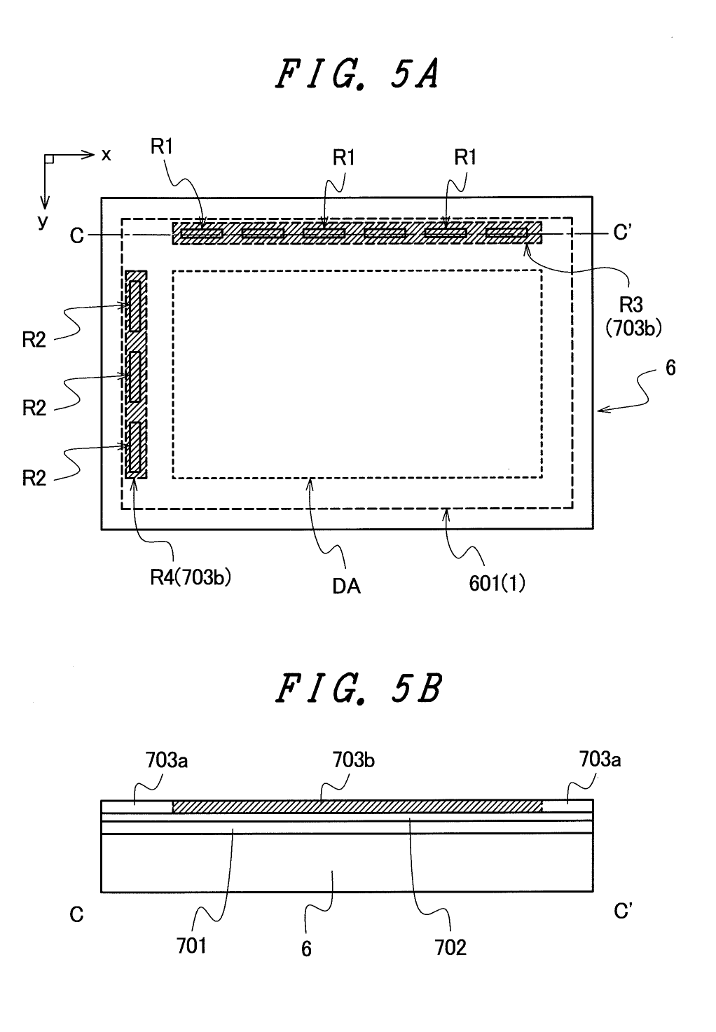

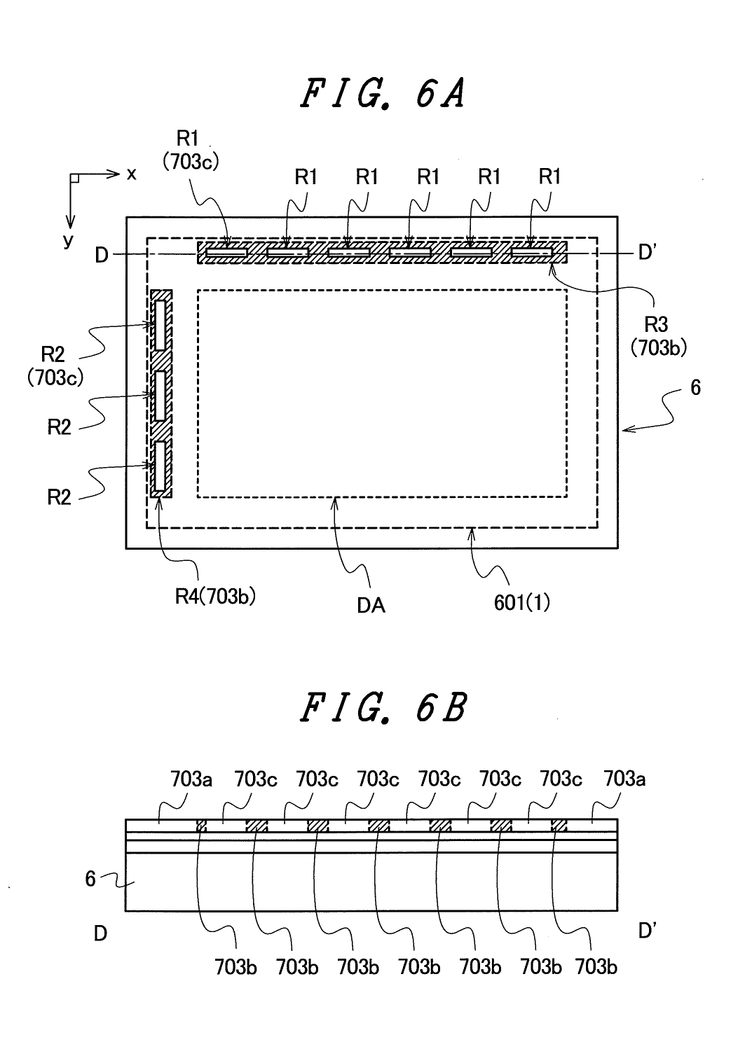

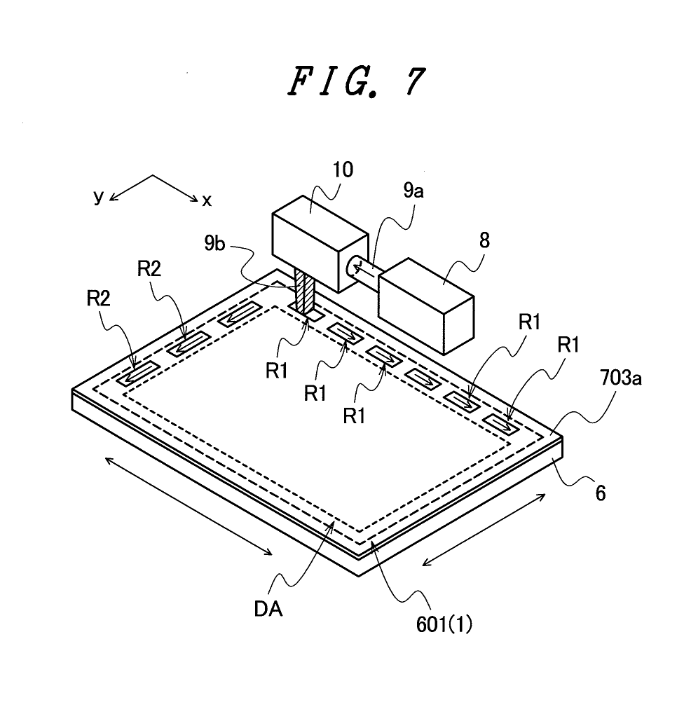

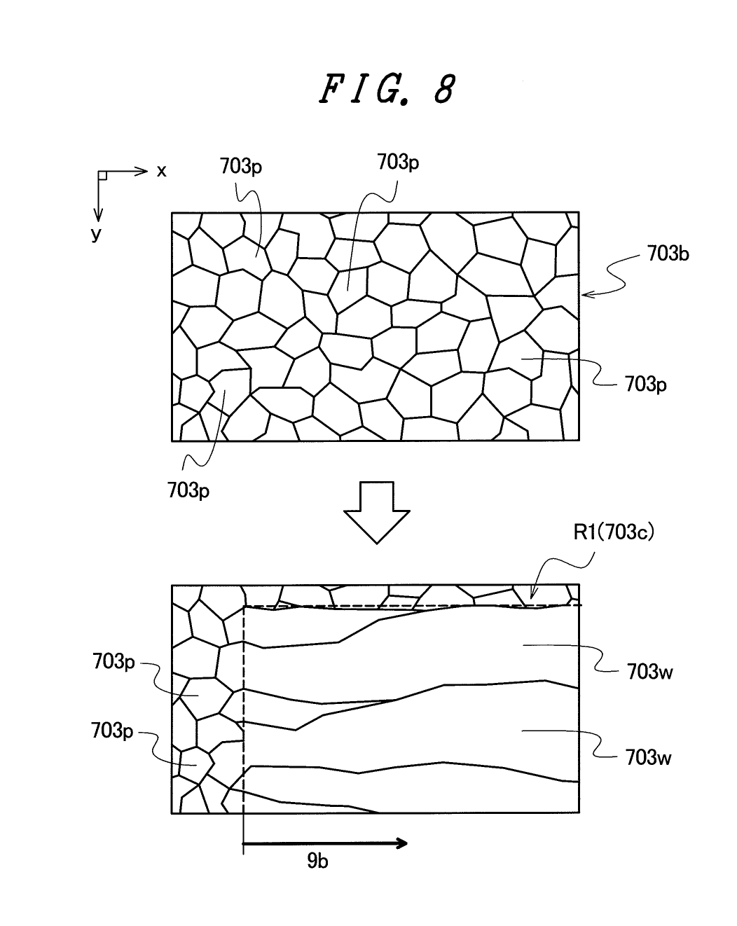

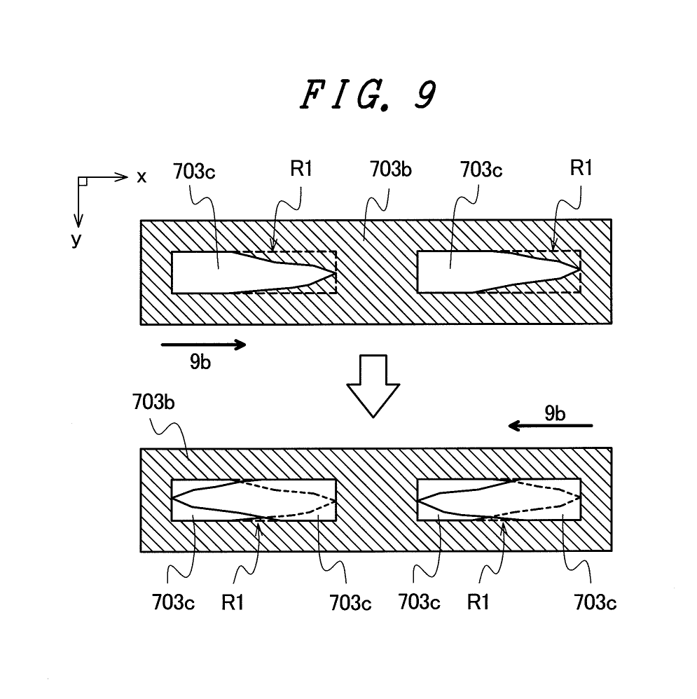

FIG. 4A is a schematic plan view of a mother glass immediately after forming an amorphous silicon film thereon. FIG. 4B is a schematic cross-sectional view showing the cross-sectional constitution taken along a line B-B′ in FIG. 4A. FIG. 5A is a schematic plan view of the mother glass immediately after forming a portion of the amorphous silicon film into poly-crystalline silicon. FIG. 5B is a schematic cross-sectional view showing the cross-sectional constitution taken along a line C-C′ in FIG. 5A. FIG. 6A is a schematic plan view of the mother glass immediately after forming the poly-crystalline silicon region into pseudo single crystal. FIG. 6B is a schematic cross-sectional view showing the cross-sectional constitution taken along a line D-D′ in FIG. 6A. FIG. 7 is a schematic perspective view for explaining methods for forming the poly-crystalline silicon and the pseudo single crystal. FIG. 8 is a schematic plan view showing a mode in which poly-crystalline silicon is formed into pseudo single crystal. FIG. 9 is a schematic plan view for explaining steps for forming pseudo single crystal to which the present invention is applied.

In the embodiment 1, the explanation is made with respect to the manufacturing method of the TFT substrate 1 in which a semiconductor layer of a TFT element which is arranged in each pixel of a display region DA is made of amorphous silicon, and semiconductor layers of semiconductor elements of a first drive circuit DRV1 and a second drive circuit DRV2 are made of pseudo single-crystalline silicon. Here, in the embodiment 1, the pseudo single-crystalline silicon implies poly-crystalline silicon which is constituted of a mass of strip-like crystals which elongates in a specific direction as described later. Further, in the embodiment 1, the explanation is made only with respect to a step related to the present invention, that is, the step for forming pseudo single-crystalline silicon.

The TFT substrate 1 is, for example, as shown in FIG. 4A, manufactured using a glass substrate having an area wider than a substrate size used in a liquid crystal display panel (hereinafter, referred to as a mother glass) 6. Here adopted is a method in which a region 601 of the mother glass 6 corresponds to a substrate size of the TFT substrate 1 used in the liquid crystal display panel, and the scanning signal lines GL, the video signal lines DL, the TFT elements, the pixel electrodes PX of the display region DA and the like are formed on the region 601 by repeating film forming and patterning a plurality of times and, thereafter, the region 601 of the mother glass 6 is cut out as a TFT substrate 1. Further, the first drive circuit DRV1 is formed on the region R1 arranged outside the display region DA, and the second drive circuit DRV2 is formed on the region R2 arranged outside the display region DA. Here, one, two, four or ten and some regions are cut out as the TFT substrates 1 from one mother glass 6.

In the manufacturing method of the embodiment 1, amorphous silicon which is used as a material of the semiconductor layer of the TFT element of each pixel in the display region DA and pseudo single-crystalline silicon which is used as a material of the semiconductor layers of semiconductor elements of the first drive circuit DRV1 and the second drive circuit DRV2 are formed such that an amorphous silicon film is formed over the whole surface of the mother glass 6 and, thereafter, for example, amorphous silicon in the region R1 and the region R2 is formed into poly-crystalline silicon, and regions which are formed into poly-crystalline silicon are formed into pseudo single-crystalline silicon. For this end, first of all, for example, as shown in FIG. 4A and FIG. 4B, on a silicon nitride film (SiN film) 701 and a silicon oxide film (SiO film) 702 which are stacked on a surface of the mother glass 6, an amorphous silicon film 703a is formed. The amorphous silicon film 703a is, for example, formed by a plasma CVD method. Further, the amorphous silicon film 703a is formed over the whole surface of the mother glass 6 such that the amorphous silicon film 703a is formed not only on the display region DA but also on the region R1 on which the first drive circuit is formed and the region R2 on which the second drive circuit is formed.

Next, for example, as shown in FIG. 5A and FIG. 5B, amorphous silicon 703a in a region R3 including the region R1 which forms the first drive circuit thereon and a region R4 including the region R2 which forms the second drive circuit thereon is formed into poly-crystalline silicon 703b. In forming the respective regions R3, R4 into poly-crystalline silicon 703b, first of all, a pulse oscillation laser beam such as an excimer laser beam or a continuous oscillation laser beam is radiated to the respective regions R3, R4 so as to dehydrogenate the amorphous silicon 703a. Then, the pulse oscillation laser beam such as the excimer laser beam or the continuous oscillation laser beam is radiated again to the dehydrogenated amorphous silicon to melt the amorphous silicon and, thereafter, the melted amorphous silicon is crystallized. Here, poly-crystalline silicon 703b of the respective regions R3, R4 is, for example, in a state that granular crystals having an extremely small particle size are gathered and solidified.

Next, for example, as shown in FIG. 6A and FIG. 6B, out of the regions R3, R4 which are formed into poly-crystalline silicon, poly-crystalline silicon 703b of the region R1 which forms the first drive circuit thereon and the region R2 which forms the second drive circuit thereon is melted and recrystalized thus forming pseudo single-crystalline silicon 703c which is constituted of a mass of strip-like crystals elongated in the specific direction. Here, to the region R1 which forms the first drive circuit thereon, for example, as shown in FIG. 7, the continuous oscillation laser beam 9agenerated by a laser oscillator 8 is radiated after being converted into strip-like energy beam 9b by an optical system 10 to melt and recrystalize poly-crystalline silicon 703b. Further, energy beam 9b (continuous oscillation laser beam 9a) to be radiated is, for example, radiated while moving the mother glass 6 in the −x direction, and while controlling the radiation/non-radiation using a mechanical shutter or a modulator (for example, an EO modulator or an AO modulator), and the energy beam 9b is sequentially radiated to the plurality of regions R1 which are arranged in parallel in the x direction thus forming poly-crystalline silicon into pseudo single crystal.

Here, a crystal state of the region R1 which forms the first drive circuit thereon is changed as shown in FIG. 8, for example. Poly-crystalline silicon 703b immediately after forming amorphous silicon 703a into poly-crystals is, for example, as shown in an upper side of FIG. 8, in a state of a mass of isotropic granular crystals 703p in which each crystal has an extremely small particle size. When poly-crystalline silicon 703b is melted and recrystalized by radiating the energy beam 9b having specific energy density while moving the energy beam 9b at a specific speed in the x direction, the melted silicon is crystallized. In this crystallization, a grain growth which is referred to as a super lateral growth occurs and, as shown in a lower side of FIG. 8, poly-crystalline silicon which is constituted of a mass of strip-like crystals 703w which is elongated in the moving direction (x direction) of the radiation position of the energy beam 9b (pseudo single-crystalline silicon 703c) is formed. Accordingly, informing the first drive circuit DRV1, for example, by forming a MOS transistor while substantially aligning the moving direction of the carrier and the longitudinal direction of the strip-like crystals 703w with each other, the mobility of the carrier of the MOS transistor can be enhanced thus achieving a high-speed operation.

Further, in the manufacturing method of the TFT substrate 1 of the embodiment 1, a shape of the energy beam 9b (continuous oscillation laser beam) which is radiated for forming pseudo single-crystalline silicon 703c is preferably, for example, set such that a size of the energy beam 9b along the moving direction (short-axis direction) of the radiation region is set approximately 3 to 5 μm and a size of the energy beam 9b along the direction orthogonal to the moving direction of the radiation region (long-axis direction) is set to 1 mm or more. A size of the laser beam along a short-axis direction may be as small as possible, preferably 5 μm or smaller.

However, the inventors of the present invention have found a following phenomenon. For example, the energy beam 9b to be radiated is, for example, the single beam having laser power of 30 W or more or the continuous oscillation laser beam formed of a synthesized beam having laser power of 30 W or more in total at an oscillation source, and the beam is radiated by condensing using an object lens. In such a case, as shown in an upper side of FIG. 9, when the energy beam 9b is radiated to one region out of the region R1 which form the first drive circuit thereon while moving the radiation position of the energy beam 9b in the first direction (+x direction), in the region where the pseudo single-crystalline silicon 703c is formed, a size of the region in the y direction orthogonal to the +x direction at a position where the radiation of the energy beam 9b is finished becomes smaller than the size of the region in the y direction at a position where the radiation of the energy beam 9b is started.

Here, the region in which the pseudo single-crystalline silicon 703c is formed in each region R1 shown in an upper side of FIG. 9 is, for example, as shown in a lower side of FIG. 8, formed as a mass of a plurality of strip-like crystals 703w.

It is estimated that such a phenomenon occurs due to a reason that, for example, a focal point of a continuous oscillation laser beam is deviated in the course of scanning due to the deformation of the object lens which condenses the continuous oscillation laser beam attributed to the temperature elevation. Here, the condensed laser power at a point of time that the continuous oscillation laser beam is radiated to the poly-crystalline silicon 703b is approximately 20 W. Accordingly, if it is possible to radiate the continuous oscillation laser beam (energy beam 9b) while correcting the deviation of the focal point, it is possible to obviate such a phenomenon. However, such a correction is extremely difficult.

Accordingly, in the manufacturing method of the TFT substrate 1 of the embodiment 1, as shown in an upper side of FIG. 9, the pseudo single-crystalline silicon 703c is formed in the first region in each region R1 which forms the first drive circuit thereon while moving the radiation position of the energy beam 9b (continuous oscillation laser beam) on the substrate in the +x direction and, thereafter, as shown in a lower side of FIG. 9, the pseudo single-crystalline silicon 703c is formed in the second region in each region R1 which forms the first drive circuit thereon while moving the radiation position of the energy beam 9b on the substrate in the −x direction. With respect to the pseudo single-crystalline silicon 703c (second region) which is formed in each region R1 when the radiation position of the energy beam 9b is moved in the −x direction, in the same manner as the pseudo single-crystalline silicon 703c (first region) which is formed while moving the radiation position in the +x direction, the size of the pseudo single-crystalline silicon 703c in the y direction at the position where the radiation of the energy beam 9b is finished becomes smaller than the size of the pseudo single-crystalline silicon 703c in the y direction at the position where the radiation of the energy beam 9b is started. However, at the position where the radiation of the energy beam 9b for forming the second region while moving the radiation position of the energy beam 9b in the −x direction is finished, the pseudo single-crystallization is already finished when the radiation position of the energy beam 9b for forming the first region is moved in the +x direction. Further, the position where the radiation of the energy beam 9b is finished when the radiation position of the energy beam 9b is moved in the −x direction is arranged in the vicinity of the position where the radiation of the energy beam 9b is started when the radiation position of the energy beam 9b is moved in the +x direction. Accordingly, even when the size of the pseudo single-crystalline silicon in the y direction at the position where the radiation of the energy beam 9b is finished in the second region which is formed into the pseudo single crystals at the time of moving the energy beam 9b in the −x direction is small, outside the second region, the pseudo single-crystalline silicon 703c in the first region which is formed when the radiation position of the energy beam 9b is moved in the +x direction is present.

In this manner, by partially overlapping the second region to the first region where the pseudo single-crystalline silicon 703c is already formed, it is possible to form the substantially whole area of the region R1 which forms the first drive circuit thereon into the pseudo single-crystalline silicon 703c. Further, by aligning the position of the center axis along the extending direction (x direction) of the first region and the position of the center axis along the extending direction of the second region with each other, it is possible to prevent the size of the pseudo single-crystalline silicon 703c from becoming smaller along the moving direction of the radiation position of the energy beam 9b.

Further, although the repeated explanation is omitted, in forming the poly-crystalline silicon 703b of the region R2 which forms the second drive circuit thereon into pseudo single crystals, for example, a positional relationship between the laser oscillator 8 and the optical system 10 with the mother glass 6 may be rotated by 90 degrees, pseudo single-crystalline silicon 703c may be formed in the region R2 which forms the second drive circuit thereon while moving the radiation position of the energy beam 9b (continuous oscillation laser beam) in the +y direction and, thereafter, pseudo single-crystalline silicon 703c may be formed in the region R2 which forms the second drive circuit thereon while moving the radiation position of the energy beam 9b in the -y direction such that the energy beam 9b partially overlaps the pseudo single-crystalline silicon 703c. Due to such an operation, pseudo single-crystalline silicon 703c of the region R2 which forms the second drive circuit thereon is formed of a mass of strip-like crystals 703w which is elongated in the y direction. Accordingly, in forming the second drive circuit DRV2, for example, by forming a MOS transistor such that the moving direction of the carrier becomes the longitudinal direction of the strip-like crystals 703w, the mobility of the carrier of the MOS transistor can be enhanced thus acquiring a high-speed operation.

Here, in views shown in upper and lower sides of FIG. 9, the first region and the second region which form pseudo single-crystalline silicon 703c thereon are respectively, for example, as shown in a lower side of FIG. 8, constituted as a mass of a plurality of strip-like crystals 703w.

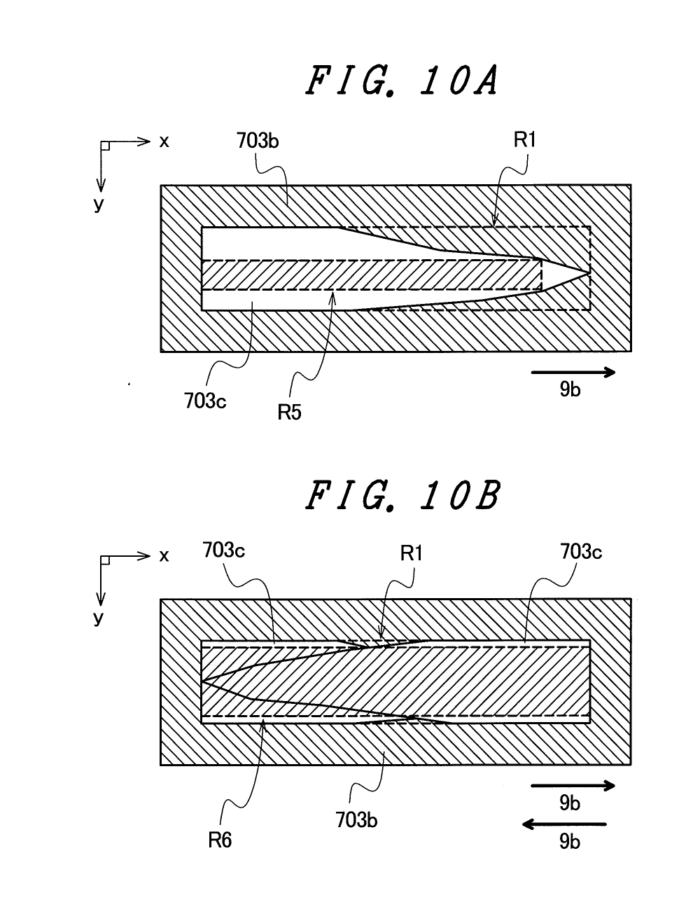

FIG. 10A and FIG. 10B are schematic views for explaining another manner of operation and advantageous effects of the manufacturing method of the TFT substrate of the embodiment 1.

FIG. 10A is a schematic plan view for explaining drawbacks when pseudo single-crystalline silicon is formed by radiating a continuous oscillation laser beam in one direction. FIG. 10B is a schematic view for explaining the manner of operation and advantageous effects when the laser beam is radiated by a method adopted by the embodiment 1.

In case of the manufacturing method of the TFT substrate 1 shown in FIG. 10A, for example, in forming poly-crystalline silicon 703b of the region R1 which forms the first drive circuit arranged in parallel in the x direction into pseudo single crystals, the continuous oscillation laser beam (energy beam 9b) is radiated while moving the radiation position of the continuous oscillation laser beam (energy beam 9b) on the substrate (mother glass 6) in the +x direction. Here, when the pseudo single-crystallization is performed by radiating the continuous oscillation laser beam while moving the radiation position of the continuous oscillation laser beam only in the +x direction, the size of the pseudo single-crystallized region in the y direction is gradually decreased from a midst portion of the region. Accordingly, for example, when the size of the laser beam in the y direction at the position where the radiation of the continuous oscillation laser beam is started is substantially equal to the size of the region R1 which forms the first drive circuit thereon in the y direction, the size of the laser beam in the y direction at the position where the radiation of the continuous oscillation laser beam is finished becomes extremely narrow compared to the size of the region R1 which forms the first drive circuit thereon in the y direction. Accordingly, in forming the region R1 which forms the first drive circuit thereon into a rectangular shape, a size of an effective region R5 which is indicated by parallel hatching in FIG. 10A becomes extremely small compared to the original region R1. That is, to increase the size of the effective region R5 to the size of the original region R1, it is necessary to increase the size of the continuous oscillation laser beam in the y direction at the time of starting radiation and hence, a quantity of the beam radiated to the outside of the region R1 which forms the first drive circuit thereon is increased resulting in the increase of a loss of energy.

To the contrary, as in the case of the embodiment 1, by forming one region R1 which forms the first drive circuit thereon into pseudo single crystals while moving the radiation position of the continuous oscillation laser beam in the first direction (+x direction) and, thereafter, by forming the region R1 into pseudo single crystals while moving the radiation position of the continuous oscillation laser beam in the second direction (−x direction) opposite to the first direction in a partially overlapping manner, the region in which the size in the y direction is decreased when the pseudo single crystallization is performed while moving the radiation position in the first direction is close to the position where the radiation of the continuous oscillation laser beam is started when the pseudo single crystallization is performed while moving the radiation position in the second direction and hence, the size in the y direction is increased. Accordingly, in forming the region R1 which forms the first drive circuit thereon into a rectangular shape, the size of an effective region R6 indicated by parallel hatching in FIG. 10B becomes substantially equal to the size of the original region R1. That is, in setting the size of the effective region R6 to the size of the original region R1, a quantity of beam radiated to the outside of the region R1 which forms the first drive circuit thereon can be reduced thus acquiring an advantageous effect that a loss of energy can be decreased.

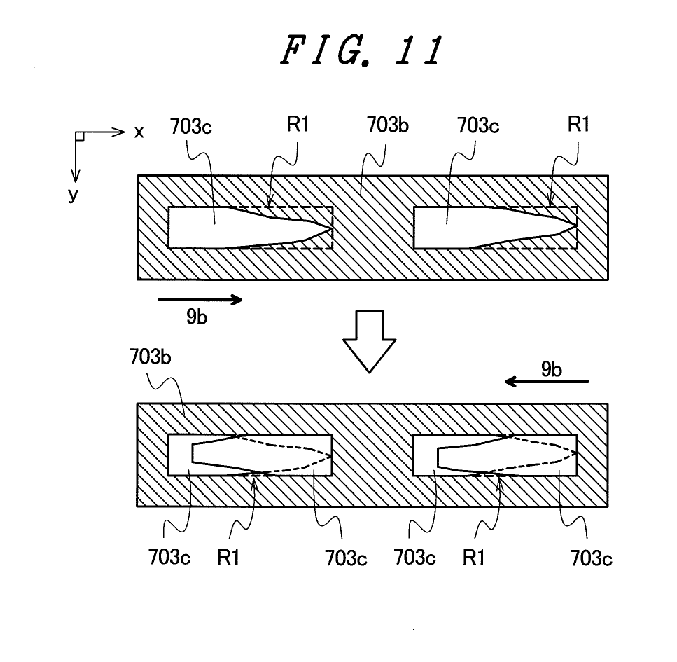

FIG. 11 is a schematic view for explaining a first modification of the manufacturing method of the TFT substrate in the embodiment 1.

The manufacturing method of the TFT substrate 1 of the embodiment 1 is mainly characterized in that, for example, pseudo single-crystalline silicon 703c is formed on the substantially rectangular region of the semiconductor film formed on the substrate (mother glass 6) while moving the radiation position of the continuous oscillation laser beam (energy beam 9b) in the first direction and, thereafter, pseudo single-crystalline silicon 703c is formed on the rectangular region while moving the radiation position of the continuous oscillation laser beam in the second direction opposite to the first direction and hence, out of the region on which pseudo single-crystalline silicon 703c is formed when the radiation position of the continuous oscillation laser beam is moved in the first direction, the region in which the size in the direction orthogonal to the first direction is decreased is reduced. That is, in radiating the continuous oscillation laser beam while moving the radiation position of the continuous oscillation laser beam in the second direction, it is sufficient to reduce the region whose size in the direction orthogonal to the first direction is decreased out of the region on which the pseudo single-crystalline silicon 703c is formed when the radiation position of the continuous oscillation laser beam is moved in the first direction. Accordingly, for example, in radiating the continuous oscillation laser beam while moving the radiation position of the continuous oscillation laser beam in the first direction, as shown in an upper side of FIG. 11, pseudo single-crystalline silicon 703c is formed by radiating the continuous oscillation laser beam by a quantity corresponding to a length of the region R1 which forms the first drive circuit thereon in the x direction, while in radiating the continuous oscillation laser beam while moving the radiation position of the continuous oscillation laser beam in the second direction, as shown in a lower side of FIG. 11, a moving quantity of the radiation position of the continuous oscillation laser beam is shortened than the length of the region R1 on which the first drive circuit is formed in the x direction thus finishing the formation of the pseudo single-crystalline silicon 703c in front of the radiation start position at the time of radiating the continuous oscillation laser beam while moving the continuous oscillation laser beam in the first direction.

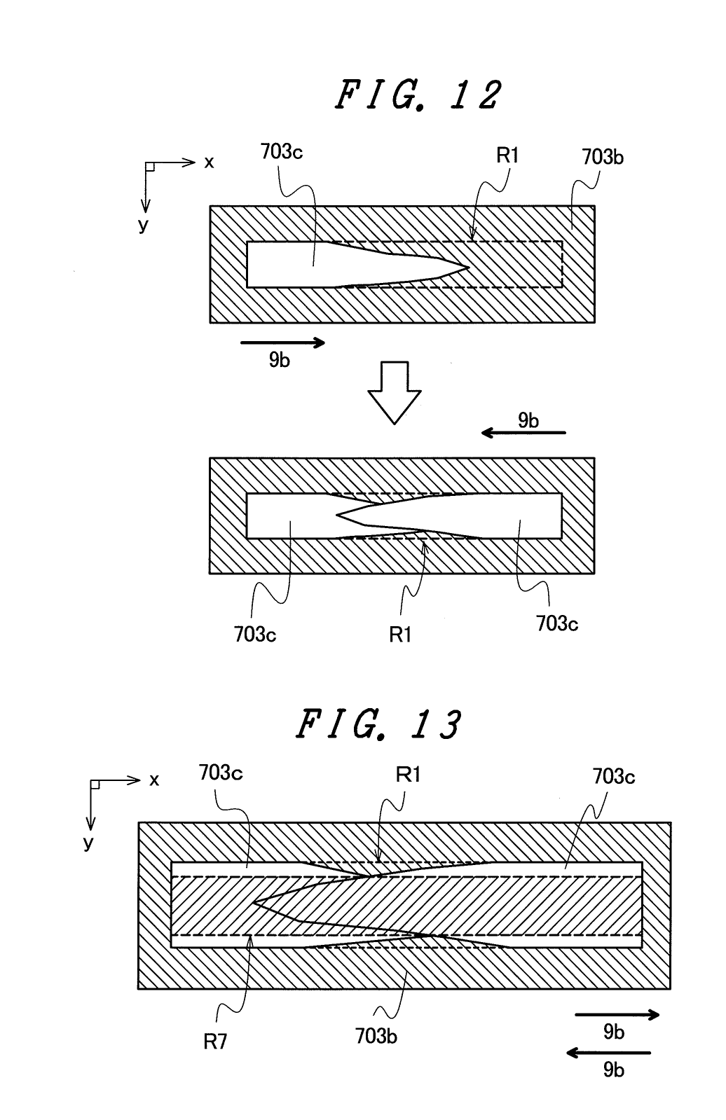

FIG. 12 and FIG. 13 are schematic views for explaining a second modification of the manufacturing method of the TFT substrate in the embodiment 1.

FIG. 12 is a schematic plan view for explaining the second modification for forming the pseudo single crystals. FIG. 13 is a schematic plan view showing an effective region when the pseudo single crystals are formed using a method shown in FIG. 12.

In explaining the technical feature of the manufacturing method of the TFT substrate 1 of the embodiment 1, in the example shown in FIG. 9, the radiation start position at the time of forming pseudo single-crystalline silicon 703c while moving the radiation position of the continuous oscillation laser beam (energy beam 9b) in the first direction agrees with the radiation finish position at the time of forming pseudo single-crystalline silicon 703c while moving the radiation position of the continuous oscillation laser beam in the second direction, while the radiation finish position at the time of forming pseudo single-crystalline silicon 703c while moving the radiation position of the continuous oscillation laser beam in the first direction agrees with the radiation start position at the time of forming pseudo single-crystalline silicon 703c while moving the radiation position of the continuous oscillation laser beam in the second direction. Further, in the example shown in FIG. 11, the radiation finish position at the time of forming pseudo single-crystalline silicon 703c while moving the radiation position of the continuous oscillation laser beam (energy beam 9b) in the first direction agrees with the radiation start position at the time of forming pseudo single-crystalline silicon 703c while moving the radiation position of the continuous oscillation laser beam in the second direction. However, it is needless to say that a relationship between the radiation start position and the radiation finish position is not limited to such a relationship and various relationships can be established. That is, the radiation start position at the time of forming pseudo single-crystalline silicon 703c in the first region while moving the radiation position of the continuous oscillation laser beam (energy beam 9b) in the first direction and the radiation finish position at the time of forming pseudo single-crystalline silicon 703c in the second region while moving the radiation position of the continuous oscillation laser beam in the second direction may be deviated from each other in the moving direction (x direction) of the radiation position of the continuous oscillation laser beam as shown in FIG. 12, for example. In the same manner, the radiation finish position at the time of forming pseudo single-crystalline silicon 703c in the first region while moving the radiation position of the continuous oscillation laser beam in the first direction and the radiation start position at the time of forming pseudo single-crystalline silicon 703c in the second region while moving the radiation position of the continuous oscillation laser beam in the second direction may also be deviated in the moving direction (x direction) of the radiation position of the continuous oscillation laser beam as shown in FIG. 12, for example.

Here, in deviating the radiation start position and the radiation finish position of the continuous oscillation laser beam at the time of forming pseudo single-crystalline silicon 703c in the first region as well as the radiation start position and the radiation finish position of the continuous oscillation laser beam at the time of forming pseudo single-crystalline silicon 703c in the second region in the moving direction of the radiation position, for example, the position at which the radiation of energy beam for forming pseudo single-crystalline silicon in the first region is finished is arranged on a side closer to a position at which the radiation of energy beam for forming pseudo single-crystalline silicon in the second region is started than a center position between the position at which the radiation of energy beam for forming pseudo single-crystalline silicon in the first region is started and the position at which the radiation of energy beam for forming pseudo single-crystalline silicon in the second region is started.

Due to such a constitution, for example, as expressed by an effective region R7 indicated by parallel hatching in FIG. 13, the size of the effective region R7 in the y direction becomes smaller than the size in the y direction of the original region R1. However, for example, corresponding to the reduction of the size in the y direction, the size of the effective region R7 in the x direction can be elongated than the size of the effective region R5 in the x direction shown in FIG. 10A or the size of the effective region R6 in the x direction shown in FIG. 10B.

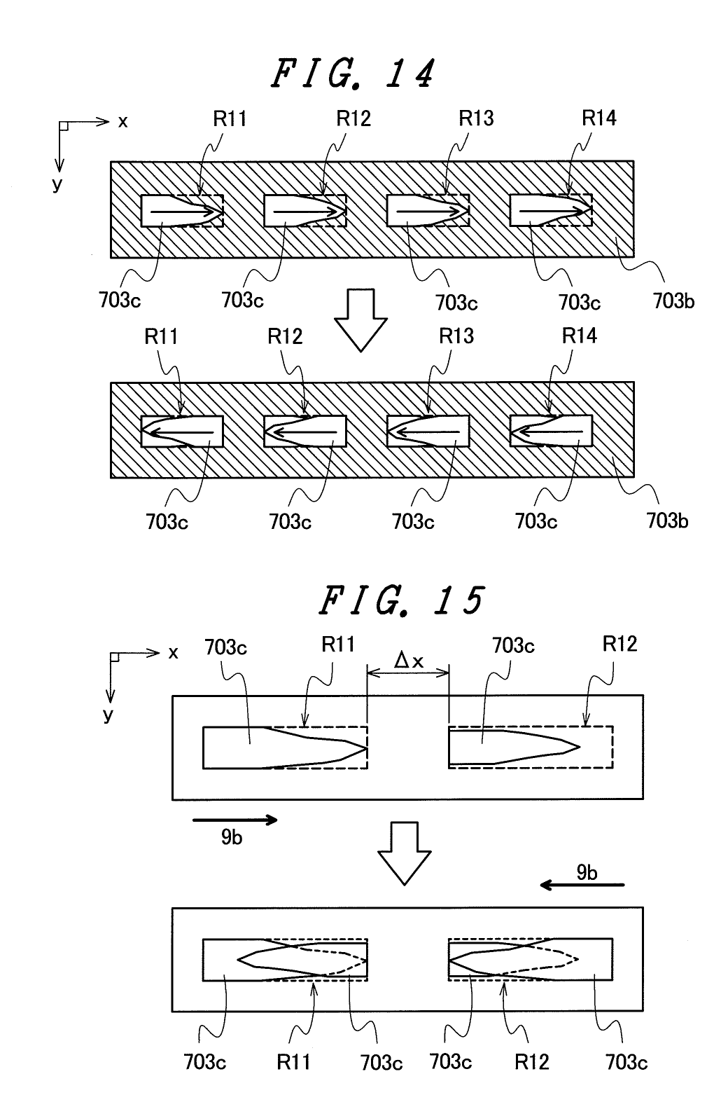

FIG. 14 to FIG. 16 are schematic views for explaining a third modification of the manufacturing method of the TFT substrate in the embodiment 1.

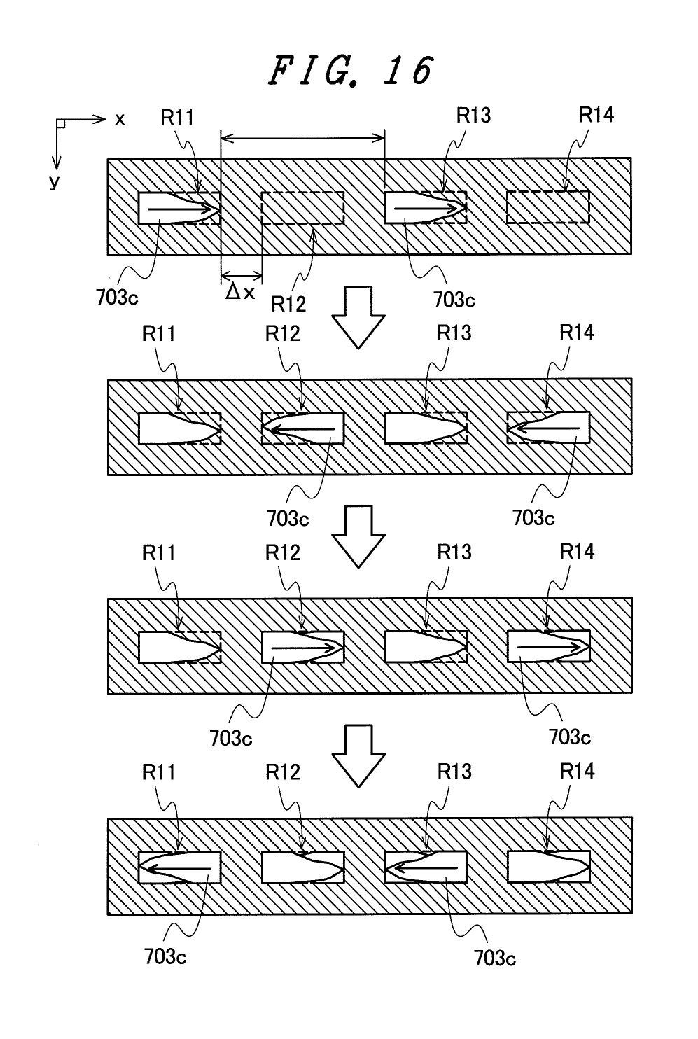

FIG. 14 is a schematic plan view for explaining one example of a radiation method of the continuous oscillation laser beam in forming a plurality of regions arranged in parallel in the x direction into pseudo single crystals. FIG. 15 is a schematic plan view showing drawbacks which may arise when a continuous oscillation laser beam is radiated by the method shown in FIG. 14. FIG. 16 is a schematic view for explaining one example of the radiation method of the continuous oscillation laser beam for overcoming the drawback shown in FIG. 15.

In the manufacturing method of the TFT substrate 1 of the embodiment 1, for example, in forming pseudo single-crystalline silicon 703c in the region R1 which forms a plurality of first drive circuits arranged in parallel in the x direction thereon, for example, the radiation position of the continuous oscillation laser beam is controlled such that the radiation is performed only when the radiation position is in the region R1 which forms the first drive circuit thereon using a mechanical shutter, a modulator or the like while moving the radiation position of the continuous oscillation laser beam in the +x direction on the substrate. Here, for example, as shown in FIG. 14, to consider a case in which pseudo single-crystalline silicon 703c is formed in four regions R1, R12, R13, R14 arranged in parallel in the x direction, a most efficient method is as follows. First of all, as shown in an upper side of FIG. 14, the continuous oscillation laser beam is sequentially radiated to the regions R11, R12, R13, R14 while moving the radiation position of the continuous oscillation laser beam in the +x direction to form pseudo single-crystalline silicon 703c and, thereafter, as shown in a lower side of FIG. 14, the continuous oscillation laser beam is sequentially radiated to the regions R14, R13, R12, R11 while moving the radiation position of the continuous oscillation laser beam in the −x direction thus forming pseudo single-crystalline silicon 703c.

However, for example, as shown in an upper side of FIG. 15, when a distance Δx between the first region R11 and the second region R12 is short, a time interval from a point of time that the radiation of laser beam to the first region R11 is finished to a point of time that the radiation of the laser beam to the second region R12 is started is short and hence, when the laser beam is radiated to the first region R11, the deformed object lens cannot restore an original shape whereby there exists a possibility that a size of pseudo-single crystalline silicon 703C in the y direction at the position where the radiation of the laser beam to the second region R12 is started becomes small. Such a phenomenon also occurs in forming pseudo single-crystalline silicon 703c in the regions R12, R11 while moving the radiation position of the continuous oscillation laser beam in the −x direction. Accordingly, as shown in a lower side of FIG. 15, there exists a possibility that the size of pseudo-single crystalline silicon 703C in the y direction at the radiation start position at the time of radiating the laser beam while moving the radiation position of the continuous oscillation laser beam in the +x direction or at the radiation start position at the time of radiating laser beam while moving the radiation position of the continuous oscillation laser beam in the −x direction becomes small thus narrowing the effective region.

To obviate such a phenomenon, for example, as shown in FIG. 16, the radiation of laser beam to one strip region (scanning region) maybe performed in a reciprocating manner twice. Here, in the first reciprocation, the continuous oscillation laser beam is radiated to the first region R11 and the third region R13 to form pseudo single-crystalline silicon 703c in a step in which a radiation region is moved in the +x direction and, thereafter, the continuous oscillation laser beam is radiated to the fourth region R14 and the second region R12 to form pseudo single-crystalline silicon 703c in a step in which the radiation region is moved in the −x direction. Then, in the second reciprocation, the continuous oscillation laser beam is radiated to the second region R12 and the fourth region R14 to form pseudo single-crystalline silicon 703c in a step in which the radiation region is moved in the +x direction and, thereafter, the continuous oscillation laser beam is radiated to the third region R13 and the first region R11 to form pseudo single-crystalline silicon 703c in a step in which the radiation region is moved in the −x direction.

Due to such an operation, for example, the time interval from finishing of the radiation of the continuous oscillation laser beam to the first region R11 in one reciprocation to starting of the continuous oscillation laser beam to the next region R13 can be prolonged. Accordingly, the object lens which is deformed when the laser beam is radiated to the first region R11 can restore the original shape thus preventing the reduction of size of the region in the y direction at the radiation start position of the continuous oscillation laser beam in the third region R13. Further, although the repeated explanation is omitted, also in remaining steps, it is possible to prevent the reduction of the size of the region in the y direction at the radiation start position of the continuous oscillation laser beam in each region. Accordingly, with respect to the region R1 which forms the plurality of first drive circuits arranged in parallel in the x direction thereon, it is possible to increase a length of each region in the x direction and, at the same time, to shorten the distance Δx between two neighboring regions.

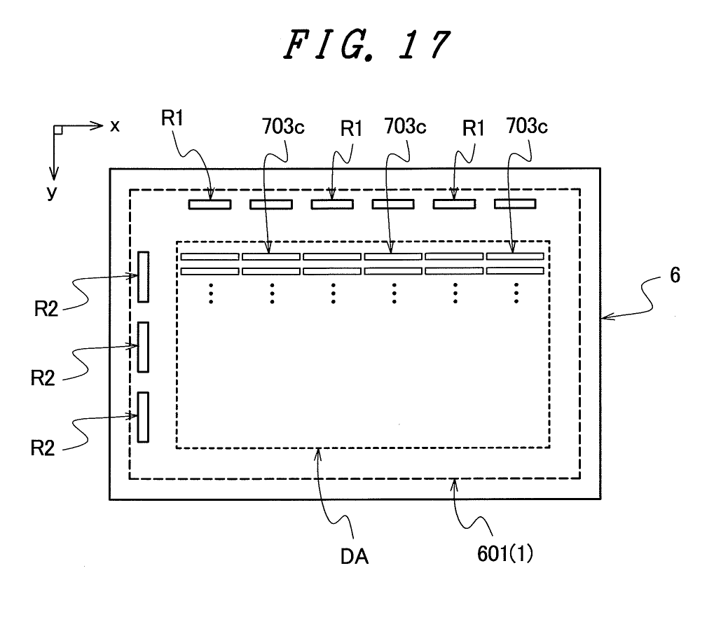

FIG. 17 is a schematic view for explaining a variation of the manufacturing method of the TFT substrate in the embodiment 1.

The embodiment 1 exemplifies the case in which, for example, as shown in FIG. 6A and FIG. 7, pseudo single-crystalline silicon 703c is formed in the region R1 which forms the first drive circuit thereon and the region R2 which forms the second drive circuit thereon arranged outside the display region DA of the TFT substrate 1. However, it is needless to say that the present invention is not limited only to such regions which form drive circuits outside the display region DA. For example, as shown in FIG. 17, the present invention is also applicable to a case in which pseudo single-crystalline silicon 703c is formed in the display region DA like tiles. When pseudo single-crystalline silicon 703c is formed in the display region DA like tiles in this manner, the steps explained in conjunction with the embodiment 1 may be adopted as steps for forming such tile-like pseudo single-crystalline silicon 703c and hence, the detailed explanation of the forming steps is omitted.

Here, as shown in FIG. 17, in forming pseudo single-crystalline silicon 703c in the display region DA like tiles, the semiconductor layer of the TFT element (switching element) of each pixel may be formed of pseudo single-crystalline silicon 703c. Accordingly, in forming each TFT element, a drain electrode and a source electrode are formed such that the longitudinal direction of the strip-like crystals which constitute pseudo single-crystalline silicon 703c and the direction of the channel length of the TFT element (moving direction of the carrier) agree with each other.

Although the present invention has been specifically explained in conjunction with the embodiment heretofore, it is needless to say that the present invention is not limited to the above-mentioned embodiment and various modifications are conceivable without departing from the gist of the present invention.

For example, it is needless to say that the present invention is not limited to the manufacturing method of the TFT substrate 1 of the liquid crystal display panel and is applicable to a manufacturing method of a substrate having the same constitution as the TFT substrate 1 of the liquid crystal display panel. That is, the present invention is applicable to a manufacturing method of a substrate such as a substrate of a self-luminous-type display panel using organic EL (Electro Luminescence) in which TFT elements are arranged in a display region as switching elements, and integrated circuits formed of semiconductor elements such as MOS transistors are formed outside a display region.

Further, the above-mentioned embodiment exemplifies the continuous oscillation laser beam as an example of the energy beam 9b to be radiated for forming pseudo single-crystalline silicon 703c. However, it is needless to say that the energy beam 9b is not limited to the continuous oscillation laser beam and a pulse oscillation laser beam such as an excimer laser beam may be radiated. Still further, it is needless to say that it is sufficient for the energy beam 9b to be radiated to melt the poly-crystalline silicon 703b and hence, the energy beam is not limited to the continuous oscillation laser beam or the pulse oscillation laser beam, and the energy beam of other mode can be used as the energy beam.

Further, the above-mentioned embodiment exemplifies the case in which the amorphous silicon film is formed into poly-crystalline silicon 703b constituted of the mass of granular crystals shown in the upper side of FIG. 8, for example, and, thereafter, the poly-crystalline silicon 703b is formed into pseudo single-crystalline silicon 703c formed of the mass of the strip-like crystals. However, it is needless to say that the present invention is not limited to such an example and pseudo single-crystalline silicon may be directly formed from the amorphous silicon film, for example. In this case, for example, it is desirable to preliminarily dehydrogenate the region of the amorphous silicon film to be formed into pseudo single-crystalline silicon.

Further, above-mentioned embodiment exemplifies the case in which the amorphous silicon film is partially formed into poly-crystalline silicon and, thereafter, pseudo single-crystalline silicon is formed in the region which is formed into poly-crystalline silicon. However, it is needless to say that the present invention is not limited to such an example and, for example, the whole surface of the amorphous silicon film formed on the mother glass 6 may be formed into poly-crystalline silicon. In this case, the semiconductor layers of the TFT elements in the display region are formed of poly-crystalline silicon.

Still further, the above-mentioned embodiment exemplifies the case in which the semiconductor layer (semiconductor material) of the TFT element (MOS transistor) is made of silicon. However, it is needless to say that the present invention is not limited to such an example and the semiconductor layer may be made of other semiconductor material.

What is claimed is:

1. A manufacturing method of a display device including a step for forming pseudo single crystal which has strip-like crystals in preset regions of a semiconductor film formed on a substrate by radiating an energy beam to the semiconductor film, the step for forming the pseudo single crystal comprising:
a first step for forming the pseudo single crystal by radiating the energy beam to a first region of the semiconductor film while moving a radiation position of the energy beam on the substrate in a first direction; and
a second step for forming the pseudo single crystal by radiating the energy beam to a second region of the semiconductor film while moving a radiation position of the energy beam on the substrate in a second direction opposite to the first direction, and
the first region and the second region in which the pseudo single crystal is formed by the respective steps consisting of the first step and the second step respectively set sizes thereof in a direction orthogonal to the moving direction of the radiation position at a position where the radiation of the energy beam is finished smaller than sizes thereof in the direction orthogonal to the moving direction of the radiation position at a position where the radiation of the energy beam is started, and
the second region includes a portion where the second region overlaps the first region and a portion where the second region does not overlap the first region.

2. A manufacturing method of a display device according to claim 1, wherein in overlapping the first region and the second region, the position where the radiation of energy beam is finished in the first step is arranged between the position where the radiation of energy beam is started in the first step and the position where the radiation of energy beam is started in the second step, and is arranged on a side closer to the position where the radiation of energy beam is started in the second step than a center position between the position where the radiation of the energy beam is started in the first step and the position where the radiation of the energy beam is started in the second step.

3. A manufacturing method of a display device according to claim 1, wherein the energy beam is a continuous oscillation laser beam.

4. A manufacturing method of a display device according to claim 1, wherein the semiconductor film before forming the pseudo single crystal is an amorphous silicon film.

5. A manufacturing method of a display device according to claim 1, wherein the semiconductor film before forming the pseudo single crystal is a poly-crystalline silicon film.

6. A manufacturing method of a display device according to claim 1, wherein a position of a center axis along the extending direction of the first region is substantially equal to a center axis along the extending direction of the second region.
